(19) United States
(12) Patent Application Publication
(10) Pub. No.: US 2026/0173423 A1
(43) Pub. Date: Jun. 18, 2026

(54) LOADING IMPROVEMENT ON CRITICAL DIMENSIONS TOP TO BOTTOM AND CHANNELS OF DIFFERENT WIDTHS IN NANOSHEET TRANSISTORS

(71) Applicant: Taiwan Semiconductor Manufacturing Co., Ltd., Hsinchu (TW)

(72) Inventors: Shu-Uei JANG, Hsinchu (TW); Chung-Shu WU, Hsinchu (TW); Yu-Lung YANG, Hsinchu (TW); Ming-Ching CHANG, Hsinchu (TW)

(73) Assignee: Taiwan Semiconductor Manufacturing Co., Ltd., Hsinchu (TW)

(21) Appl. No.: 18/984,709

(22) Filed: Dec. 17, 2024

(51) Int. Cl. H10D 30/01; H10D 30/00

(52) U.S. Cl. CPC H10D 30/0195; H10D 30/0191; H10D 30/502; H10D 30/507

(57) ABSTRACT

Provided is a method for forming semiconductor devices. This method includes forming a stack over a substrate. The stack includes multiple semiconductor portions spaced apart from one another by gaps. Next, the gaps are filled with a dielectric oxide material. End portions of the deposited dielectric oxide material are then laterally etched by an etch gas composition to form lateral openings. The etch gas composition includes a halogen-containing compound, ammonia and an amine. After forming inner spacers in the lateral openings between the adjacent semiconductor portions of the multiple semiconductor portions, the remaining portions of the deposited dielectric oxide material in the gaps are moved. A gate stack is then formed in the gaps to surround a channel region of the stack.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart of a method for fabricating a gate-all-around (GAA) device, in accordance with some embodiments of the present disclosure.

FIGS. 2-14 illustrate cross-sectional views of the GAA device during a fabrication process according to the method of FIG. 1, in accordance with some embodiments of the present disclosure.

FIGS. 15A and 15B illustrate fin structures of different widths, in accordance with some embodiments of the present disclosure.

FIG. 16A-16C illustrates etching profiles of sacrificial oxide portions.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Multi-gate devices, such as gate-all-around (GAA) transistors, have been introduced to improve gate control by increasing gate-channel coupling, minimizing OFF-state current, and mitigating short-channel effects (SCEs). Formation of a GAA transistor includes formation of a stack that includes a number of channel layers interleaved by a number of sacrificial layers, where the sacrificial layers may be selectively removed to release the channel layers as channel nanosheets. A metal gate structure, which includes multiple dielectric and conductive layers, is then formed to wrap around each of the channel nanosheets. The composition of the sacrificial layers is selected to ensure selective removal of the sacrificial layers without introducing substantial damage to the channel layers. In existing technologies, a uniform dimension of each channel nanosheet along the gate length is desired to ensure uniform gate control throughout each channel nanosheet.

Because metal gates are interleaved between channel nanosheets in a GAA transistor, inner spacers are provided between sidewalls of the metal gates and portions of epitaxial source/drain features disposed adjacent to the metal gates to reduce capacitance and prevent leaking between the metal gate and source/drain features. However, while the inner spacers generally offer the advantage of reducing capacitance in GAA transistors, the use of inner spacers introduces gate length variabilities and replacement metal gate (RMG) fabrication difficulties. For example, the gate lengths on the top and bottom surfaces of a channel nanosheet are determined by the respective dimensions of the top and bottom inner spacers. Consequently, the inner spacer critical dimension (CD) uniformity from bottom to top affects both the device and yield performance. However, in existing technologies, the lateral etching process used to form inner spacers in stacked channel nanosheet structures often results in inner spacers with non-uniform critical dimensions, both from top to bottom within the same stack and across stacks with different channel widths.

The present disclosure provides methods for forming inner spacers with uniform critical dimensions (CD) by controlling the etching rates from top to bottom in a single stack and across different stacks. This ensures a consistent gate length across all nanosheet channel surfaces, regardless of whether they have the same or different channel widths, in GAA transistors.

The GAA transistors described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA transistors.

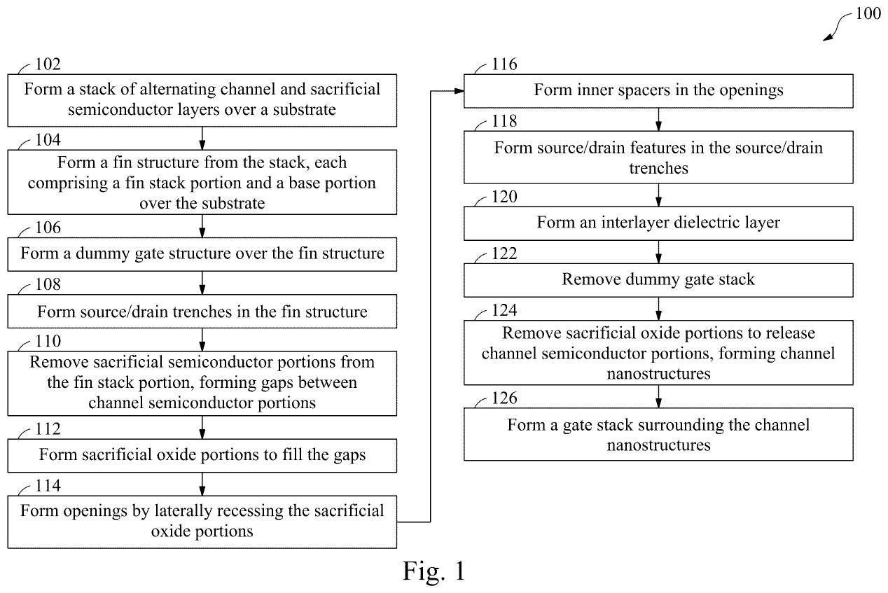

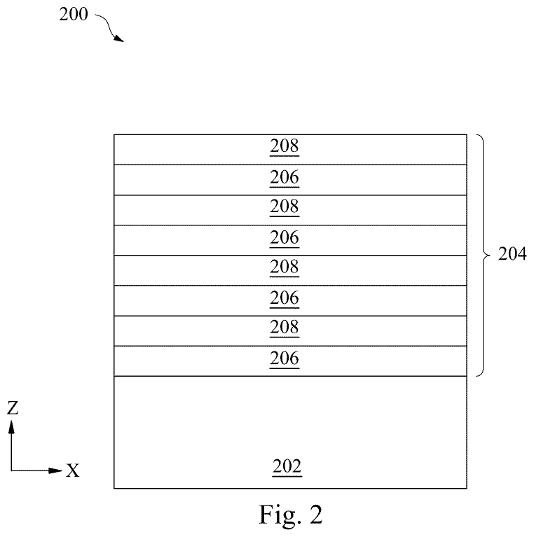

FIG. 1 is a flowchart of a method 100 of forming a GAA device 200, in accordance with some embodiments of the present disclosure. FIGS. 2-14 are cross-sectional views of the GAA device 200 at various stages of the method 100, in accordance with some embodiments. Some embodiments of method 100 are described below in conjunction with FIGS. 2-14 with reference to the GAA device 200. The method 100 is merely an example and is not intended to limit the present disclosure beyond what is explicitly recited in the claims. Additional operations can be provided before, during, and after the method 100, and some operations described can be replaced, eliminated, or moved around for additional embodiments of the method.

Referring to FIGS. 1 and 2, the method 100 includes operation 102, where an initial structure of the GAA device 200 is provided. The initial structure includes a substrate 202, a stack 204 of alternating epitaxial semiconductor layers over the substrate 202. FIG. 2 is a cross-sectional view of the GAA device 200 after forming the stack 204 of alternating epitaxial semiconductor layers over the substrate 202.

The substrate 202 can be any suitable substrate, and can be processed with various features. In some embodiments, the substrate 202 may be a semiconductor substrate such as a silicon substrate. In some embodiments, the substrate 202 includes various layers, including conductive or insulating layers formed on a semiconductor substrate. The substrate 202 may include various doping configurations. For example, different doping profiles (e.g., n wells, p wells) may be formed on the substrate 202 in regions designed for different device types (e.g., n-type FETs, p-type FETs). The suitable doping may include ion implantation of dopants and/or diffusion processes. The substrate 202 typically has isolation features (e.g., shallow trench isolation (STI) features) interposing the regions providing different device types. The substrate 202 includes other semiconductors such as germanium or diamond. Alternatively, the substrate 202 includes a compound semiconductor such as silicon carbide (SiC), gallium arsenic, gallium phosphide, indium phosphide, indium arsenide, indium antimonide; an alloy semiconductor, such as SiGe, GaAsP, AlInAs, AlGaAs, GaInAs, GaInP, GaInAsP, and/or other suitable materials. Further, the substrate 202 may optionally include an epitaxial layer, may be strained for performance enhancement, may include a silicon-on-insulator structure, and/or have other suitable enhancement features.

The stack 204 of alternative epitaxial semiconductor layers are blanketly deposited on the substrate 202. The stack 204 comprises alternating sacrificial semiconductor layers 206 and channel semiconductor layers 208, wherein each channel semiconductor layer 208 is disposed between the sacrificial semiconductor layers 206. In some embodiments, the sacrificial semiconductor layers 206 include a first semiconductor material, and the channel semiconductor layers 208 include a second semiconductor material that is different from the first semiconductor material. The materials of sacrificial semiconductor layers 206 and channel semiconductor layers 208 may be chosen based on providing different etching selectivities. For example, in some embodiments, the first semiconductor material may comprise germanium (Ge) or silicon germanium (SiGe), whereas the second semiconductor material may comprise silicon (Si). In some embodiments, the germanium content in the first semiconductor material may be between about 15 wt % and about 40 wt %. In some alternative embodiments, the first semiconductor material includes SiGe having a first Ge content and the second semiconductor material includes SiGe having a second Ge content lower than the first Ge content. In various embodiments, the sacrificial semiconductor layers 206 and the channel semiconductor layer 208 are substantially dopant-free (i.e., having an extrinsic dopant concentration less than about 1×10¹⁷ cm⁻3).

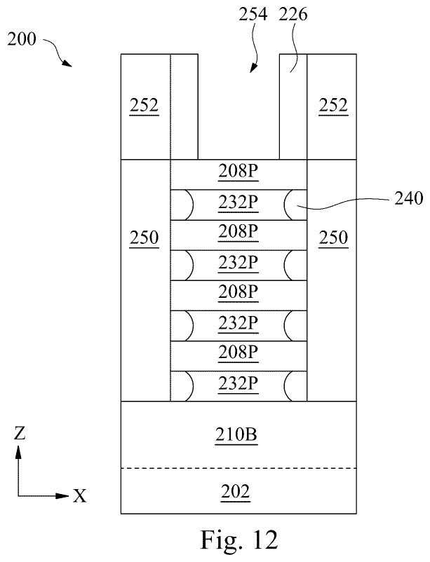

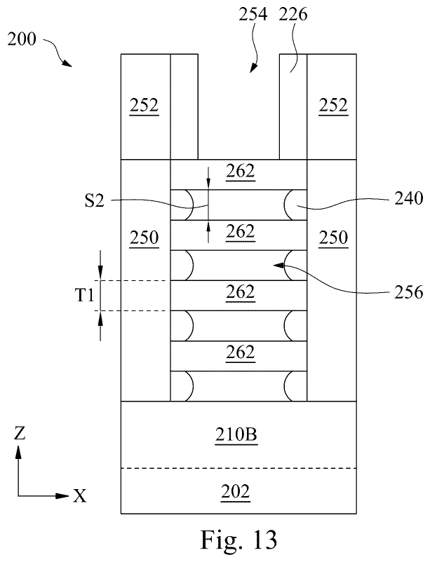

In some embodiments, the sacrificial semiconductor layers 206 may be removed in a later process, thereby leaving the channel semiconductor layers 208 which define channel nanostructures (e.g., 262 of FIG. 13) for the GAA device 200. The thickness of sacrificial semiconductor layers 206 thus determines the spacing between adjacent channel nanostructures (e.g., 262 of FIG. 12). In some embodiments, the thickness of the sacrificial semiconductor layers 206 may range from about 8 nm to about 15 nm. The thickness of the channel semiconductor layers 208 is chosen based on, for example, manufacturing considerations, transistor performance considerations, and the like. In some embodiments, the thickness of the channel semiconductor layers 208 may range from about 4 nm to about 10 nm.

The number of sacrificial semiconductor layers 206 and channel semiconductor layers 208 depends on the desired number of channel nanostructures (e.g., 262 of FIG. 12) in the GAA device 200. In some embodiments, the number of channel semiconductor layers 208 is from, for example, 2 to 10, to form a stack of 2 to 10 vertically separated channel nanostructures. In some embodiments and as illustrated in FIG. 2, the stack 204 includes four (4) layers of sacrificial semiconductor layers 206 and four (4) layers of channel semiconductor layers 208. However, it can be appreciated that any number of semiconductor layers 206, 208 can be formed in the stack 204.

The sacrificial semiconductor layers 206 and channel semiconductor layers 208 are epitaxially grown layer-by-layer from a top surface of the substrate 202. In some embodiments, the sacrificial semiconductor layers 206 and channel semiconductor layers 208 are grown by a molecular beam epitaxy (MBE) process, a chemical vapor deposition (CVD) process such as a metal organic CVD (MOCVD) process, or other suitable epitaxy growth processes. The epitaxy growth results in the sacrificial semiconductor layers 206 and the channel semiconductor layers 208 having the same crystal orientation as the substrate 202.

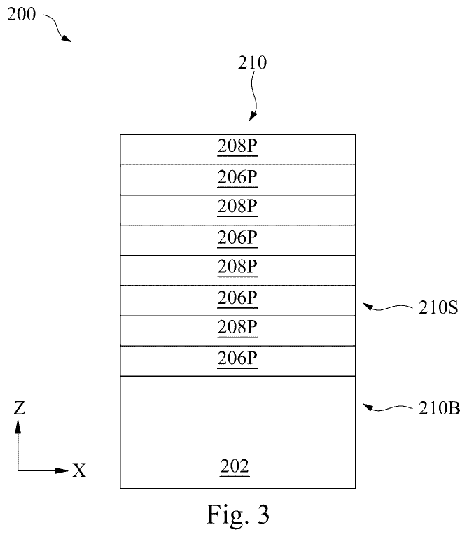

Referring to FIGS. 1 and 3, the method 100 proceeds to operation 104, where at least one fin structure 210 is formed from the stack 204, in accordance with some embodiments. FIG. 3 is a cross-sectional view of the GAA device 200 after forming the at least one fin structure 210.

In some embodiments, the stack 204 and a portion of the substrate 202 are patterned to form the at least one fin structure 210. Each fin structure 210 extends vertically along the Z-direction from the substrate 202 and has a length dimension along the X direction and a width dimension along the Y direction. Each fin structure 210 is formed to have a width ranging from about 1 nm to about 150 nm.

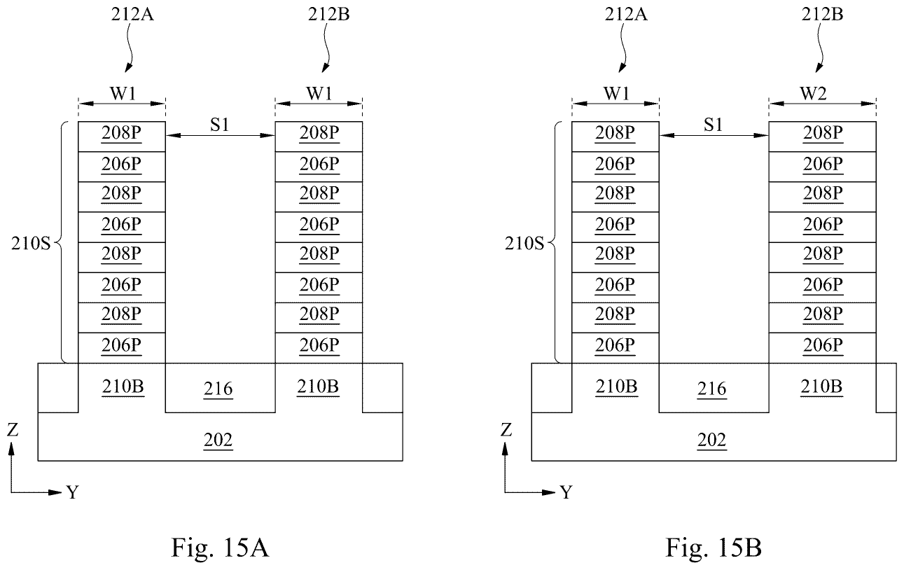

In some embodiments, operation 104 forms a plurality of fin structures, each with substantially the same width. For example, the fin structures 212A and 212B shown in FIG. 15A are formed to have the same width, denoted as W1. In other embodiments, at least two fin structures in the plurality of fin structures have different widths. As illustrated in FIG. 15B, fin structure 212A has a width W1 less than the width W2 of fin structure 212B. The width W1 may range from about 3 nm to about 80 nm, while the width W2 may range from about 20 nm to about 150 nm.

The fin structures 212A, 212B are spaced apart from each other by a spacing S1. In some embodiments, the spacing S1 ranges from about 5 nm to about 400 nm.

The fin structure 210 may include a base portion 210B and a fin stack portion 210S. The base portion 210B is formed from the substrate 202, while the fin stack portion 210S is formed from the stack 204 and includes portions of the sacrificial semiconductor layers 206 (herein referred to as sacrificial semiconductor portions 206P) and portions of the channel semiconductor layers 208 (herein referred to as channel semiconductor portions 208P).

In some embodiments, the fin structure 210 may be formed using photolithography and etching processes. During a photolithography process, a hard mask layer (not shown) may be first formed over the topmost surface of the stack 204. In some embodiments, the hard mask layer includes a dielectric material such as, for example, silicon nitride (SiN), silicon carbon nitride (SiCN), silicon oxycarbide (SiOC), silicon oxycarbon nitride (SiOCN), or a combination thereof. In some embodiments, the hard mask layer is formed by chemical CVD, plasma enhanced CVD (PECVD), physical vapor deposition (PVD), atomic layer deposition (ALD), or other suitable deposition processes. In some embodiments, the hard mask layer may have a double-layer structure including a pad oxide layer and a pad nitride layer formed over the pad oxide layer. In some embodiments, the pad oxide layer includes silicon oxide, which can be formed by thermal oxidation. The pad nitride layer includes SiN, which can be formed by CVD, PECVD, PVD, ALD, or other suitable deposition processes.

Subsequently a photoresist layer is applied to the hard mask layer by, for example, spin coating. Then, the photoresist layer is exposed according to a mask of patterns, and is developed to form the patterns in the photoresist layer. The photoresist layer with the patterns can be used as an etch mask to pattern other layers. In some embodiments, patterning the photoresist layer is performed using an extreme ultraviolet (EUV) light lithography process. The patterned photoresist layer is then used to protect regions of the substrate 202 and the sacrificial semiconductor layers 206 and channel semiconductor layers 208 formed thereupon, while an etching process forms the fin structure 210. In some embodiments, the etching process may be a dry etching process such as plasma etching or reactive ion etching (RIE), a wet etching process, or a combination thereof.

In various other embodiments, the fin structure 210 may be formed using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Mandrels are formed alongside the patterned sacrificial layer using a self-aligned process. The sacrificial layer is then removed, and the remaining mandrels are then used as an etch mask to pattern the stack 204 and the substrate 202 to provide the fin structures 210.

Subsequently, isolation feature 216 may be formed adjacent and around the base portion 210B of the fin structure 210. The isolation feature 216 is disposed between the fin structures 212A, 212B, as shown in FIGS. 15A and 15B. The isolation feature 216 may also be referred to as shallow trench isolation (STI) feature. In an example process, a dielectric layer is first deposited over the substrate 202, filling the trenches between the fin structures 212A, 212B with the dielectric material. In some embodiments, the dielectric layer may include silicon oxide, silicon nitride, silicon oxynitride, fluorine-doped silicate glass (FSG), a low-k dielectric, combinations thereof, and/or other suitable materials. In various examples, the dielectric layer may be deposited by a CVD process, a subatmospheric CVD (SACVD) process, a flowable CVD process, an atomic layer deposition (ALD) process, a physical vapor deposition (PVD) process, spin-on coating, and/or other suitable processes. The deposited dielectric material is then planarized, for example, by a chemical mechanical polishing (CMP) process. The planarized dielectric layer is further recessed by a dry etching process, a wet etching process, and/or a combination thereof to form the isolation feature(s) 216. In some embodiments, the top surface of the isolation feature 216 is substantially coplanar with or lower than bottom surfaces of the lowermost sacrificial semiconductor portions 206P.

Next, the hard mask layer, if not removed during the formation of the isolation feature 216, is removed from the topmost surfaces of the fin structure 210. The removal of the hard mask layer may be performed using an anisotropic etching process. The etching process may be a dry etching process such as RIE, a wet etching process, or a combination thereof.

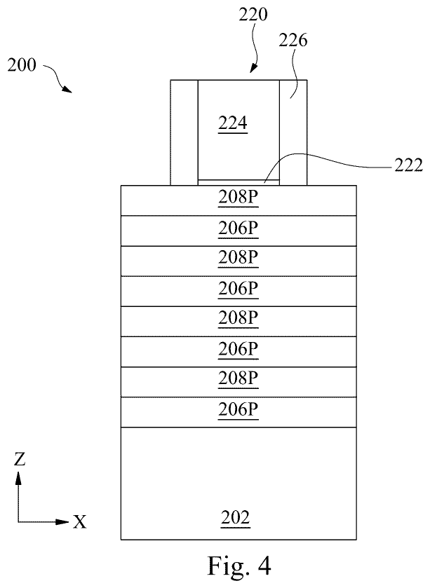

Referring to FIGS. 1 and 4, the method 100 proceeds to operation 106, where a dummy gate structure 220 is formed over the fin structure 210, in accordance with some embodiments. FIG. 4 is a cross-sectional view of the GAA device 200 after forming the dummy gate structure 220. The dummy gate structure 220 is formed across fin structure 210, along the sidewalls and the topmost surface of the fin structure 210.

The dummy gate structure 220 includes a dummy gate stack (222, 224) and gate spacers 226. In accordance with embodiments of the present disclosure, the dummy gate stack (222, 224) will be replaced with a metal gate stack.

In some embodiments, the dummy gate stack (222, 224) includes a dummy gate dielectric 222 and a dummy gate electrode 224 on the dummy gate dielectric 222. In some embodiments, the dummy gate stack (222, 224) may further include a dummy gate cap (not shown) on top of the dummy gate electrode 224.

In some embodiments, the dummy gate dielectric 222 may be made of silicon oxide, silicon nitride, or silicon oxynitride. The dummy gate electrode 224 may be made of silicon such as polycrystalline silicon or amorphous silicon. In some embodiments, the dummy gate stack (222, 224) may be formed by first conformally depositing a dummy gate dielectric layer over fin structure 210 and the isolation feature 216. A dummy gate electrode layer is then blanketly deposited on the dummy gate dielectric layer such that the fin structure 210 is fully embedded in the dummy gate electrode layer. The thickness of the dummy gate dielectric layer may range from about 1 nm to about 5 nm in some embodiments. The thickness of the dummy gate electrode layer may range from about 100 nm to about 200 nm in some embodiments. In some embodiments, the dummy gate electrode layer is subjected to a planarization operation, for example, CMP. The dummy gate dielectric layer and the dummy gate electrode layer may be deposited using CVD, PECVD, PVD, ALD, or other suitable deposition processes. Subsequently, the dummy gate dielectric layer and the dummy gate electrode layer are patterned using photolithography and etching processes. For example, a photoresist layer (not shown) is applied over the dummy gate electrode layer and lithographically patterned by lithographic exposure and development. The pattern in the photoresist layer is sequentially transferred into the dummy gate electrode layer and the dummy gate dielectric layer by at least one anisotropic etching process, thereby forming the dummy gate stack (222, 224), which comprises the remaining portions of the dummy gate dielectric layer and the dummy gate electrode layer. The anisotropic etching process may be a dry etching process, for example, RIE, a wet etching process, or a combination thereof. If not completely consumed, the remaining photoresist layer after formation of the dummy gate stack (222, 224) is removed by, for example, ashing.

The gate spacers 226 are disposed on sidewalls of the dummy gate stack (222, 224). In some embodiments, the gate spacers 226 may include a dielectric material such as, for example, an oxide, a nitride, an oxynitride, or combinations thereof. In some embodiments, the gate spacers 226 are made of silicon nitride. In some embodiments, the gate spacers 226 may be formed by first depositing a conformal gate spacer material layer on exposed surfaces of the dummy gate stack (222, 224), the fin structure 210, and the isolation feature 216 and then etching the gate spacer material layer to remove horizontal portions of the gate spacer material layer. In some embodiments, the gate spacer material layer may be deposited, for example, by CVD, PECVD, or ALD. In some embodiments, the gate spacer material layer may be etched by dry etch such as, for example, plasma etching or RIE. Vertical portions of the gate spacer material layer present on the sidewalls of the dummy gate stack (222, 224) constitute the gate spacers 226.

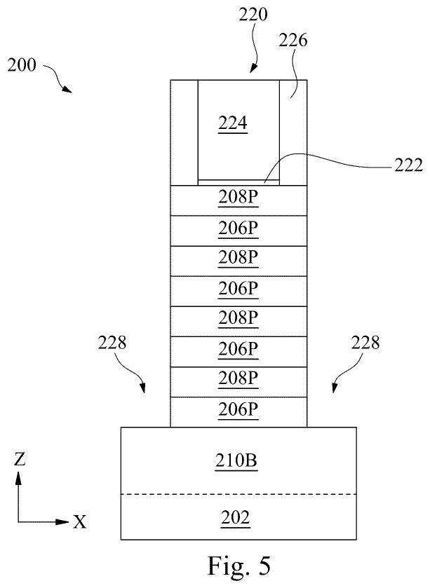

Referring to FIGS. 1 and 5, the method 100 proceeds to operation 108, where source/drain trenches 228 are formed in the fin structure 210, in accordance with some embodiments. FIG. 5 is a cross-sectional view of the GAA device 200 after forming the source/drain trenches 228.

In some embodiments, portions of the fin structure 210 in the source/drain regions are etched using the dummy gate structure 220 as an etch mask to form the source/drain trenches 228. The etching may be performed by a dry etching process such as plasma etching or RIE. An example dry etching process may implement an oxygen-containing gas, hydrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. Alternatively, the etching may be performed by a wet etching process that uses an etchant such as a mixture of ammonium hydroxide, hydrogen peroxide, and water (APM), tetramethylammonium hydroxide (TMAH), or ammonium hydroxide (NH₄OH). After etching, sidewalls of the channel semiconductor portions 208P and the sacrificial semiconductor portions 206P are exposed in the source/drain trenches 228. In some embodiments, the substrate 202 may also be partially etched. Accordingly, the bottom surfaces of the source/drain trenches 228 may be leveled with the top surface of the base portion 210B (as shown in FIG. 5) or lower than the top surface of the base portion 210B (not shown).

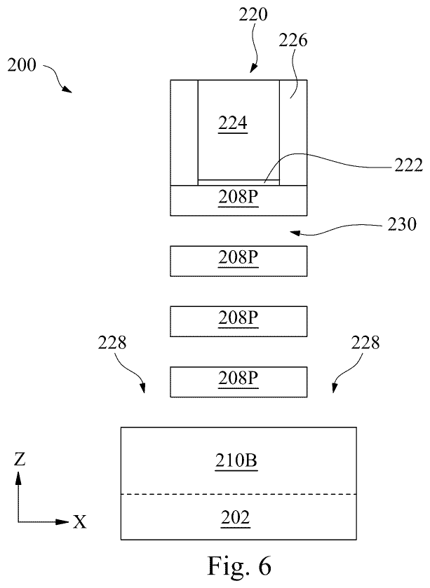

Referring to FIGS. 1 and 6, the method 100 proceeds to operation 110, where the sacrificial semiconductor portions 206P are removed, in accordance with some embodiments. FIG. 6 is a cross-sectional view of the GAA device 200 after removing the sacrificial semiconductor portions 206P.

The selective removal of the sacrificial semiconductor portions 206P releases the channel semiconductor portions 208P to form gaps 230 between adjacent channel semiconductor portions 208P and between the bottommost channel semiconductor portions 208P and the base portion 210B in fin structure 210.

In some embodiments, the sacrificial semiconductor portions 206P may be removed by a selective etching process using an etchant that is selective to the material of sacrificial semiconductor portions 206P, such that the sacrificial semiconductor portions 206P are removed without substantially attacking the channel semiconductor portions 208P. In some embodiments, the etching process is an isotropic etching process which can be a dry etching process or a wet etching process. In some embodiments, the selective etching process may include oxidizing the sacrificial semiconductor portions 206P using a suitable oxidizer, such as ozone. Thereafter, the oxidized sacrificial semiconductor portions 206P may be selectively removed. In some embodiments, when the channel semiconductor portions 208P include Si and the sacrificial semiconductor portions 206P include SiGe, the sacrificial semiconductor portions 206P may be selectively removed by applying an HCl gas at a temperature of about 500° C. to about 700° C., or applying a gas mixture of CF₄, SF₆, and CHF₃.

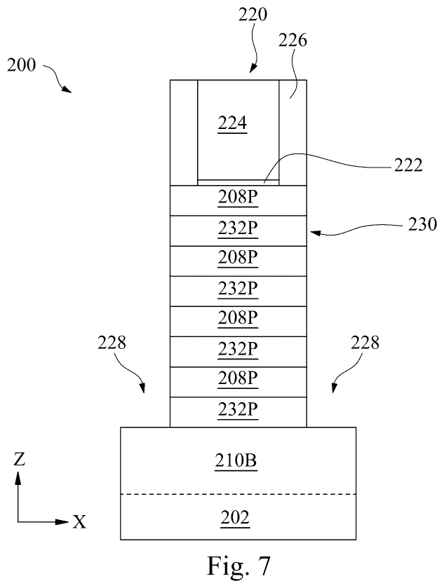

Referring to FIGS. 1 and 7, the method 100 proceeds to operation 112, where sacrificial oxide portions 232P are formed to fill the gaps 230, in accordance with some embodiments. FIG. 7 is a cross-sectional view of the GAA device 200 after forming the sacrificial oxide portions 232P to fill the gaps 230.

A sacrificial oxide layer is conformally deposited on the channel semiconductor portions 208P, the base portion 210B, and the dummy gate structure 220 to fill the gaps 230 (i.e., the spaces between adjacent channel semiconductor portions 208P). In some embodiments, the sacrificial oxide layer comprises a dielectric oxide, such as, for example, silicon oxide, silicon dioxide, or a silicon-rich oxynitride. The sacrificial oxide layer may be formed by a conformal deposition process such as CVD or ALD. In some embodiments, the thickness of the sacrificial oxide layer is controlled such that the sacrificial dielectric layer pitches off the gaps 230. In some embodiments, the sacrificial dielectric layer fully fills the gaps 230.

Next, an etching process, such as an anisotropic etching process, is performed to remove portions of the sacrificial oxide layer disposed outside the gaps 230 from the structure. In some embodiments, a wet etch or a diluent hydrofluoric acid (dHF) wash is implemented. The remaining portions of the sacrificial oxide layer in the gaps 230 form the sacrificial oxide portions 232P. In some embodiments, the sidewalls of the end portions of the sacrificial oxide portions 232P are aligned with the sidewalls of the end portions of the channel semiconductor portions 208P.

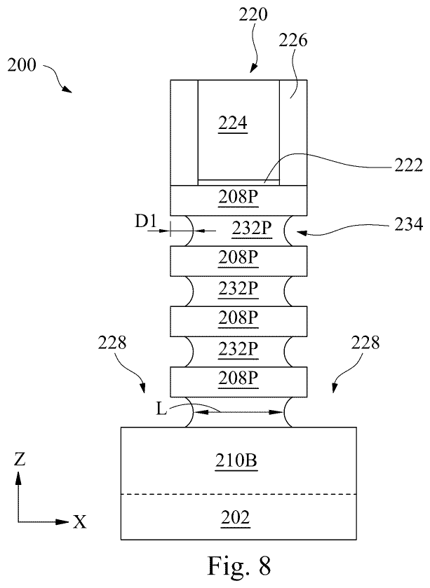

Referring to FIGS. 1 and 8, the method 100 proceeds to operation 114, where the sacrificial oxide portions 232P are recessed to form lateral openings 234, in accordance with some embodiments. FIG. 8 is a cross-sectional view of the GAA device 200 after recessing the sacrificial oxide portions 232P to form the lateral openings 234.

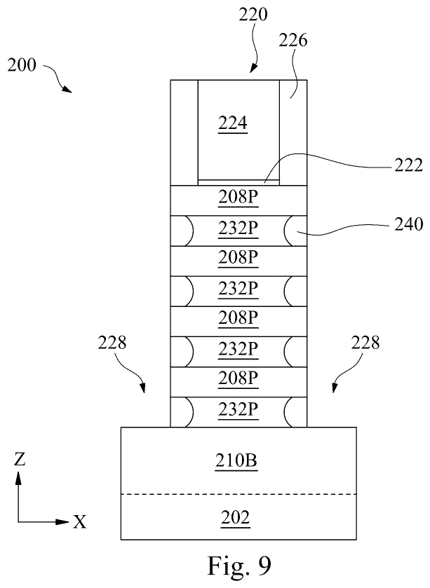

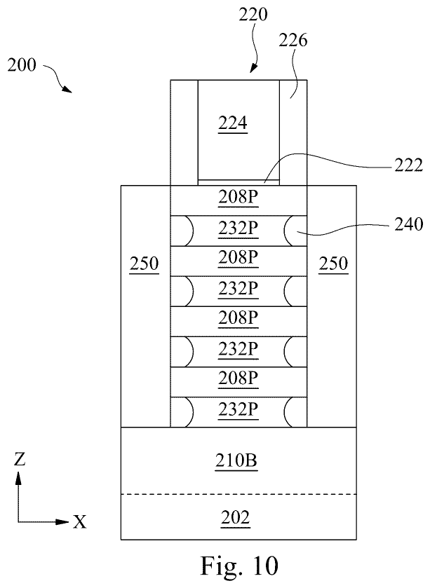

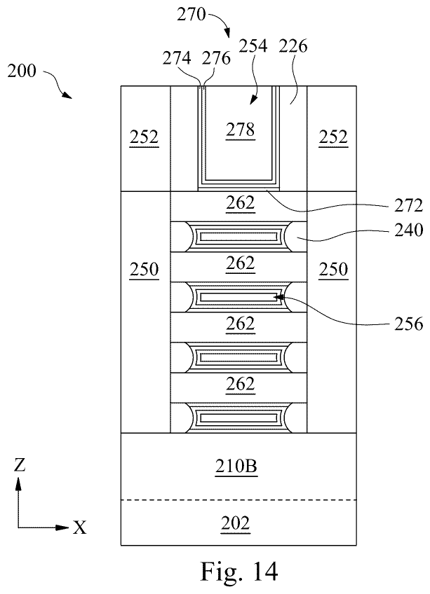

The end portions of the sacrificial oxide portions 232P exposed in the source/drain trenches 228 are selectively and laterally recessed to form the lateral openings 234, while the exposed channel semiconductor portions 208P are substantially unetched. In some embodiments, the amount of the sacrificial oxide portions 232P etched is precisely controlled to maintain adequate channel length for the metal gate stack formed in subsequent processing steps. This ensures high conductivity while preserving good yield. In some embodiments, the lateral etch distance is no greater than the width of the gate spacers 226. In some embodiments, after the selective recess in operation 114, each of the lateral openings 234 has a dimension D1 along the X direction ranging from about 4 nm to about 8 nm such that the to-be-formed inner spacers (240, shown in FIG. 9) would be thick enough to protect source/drain features (250, shown in FIG. 10) from being damaged during subsequent processes. In some embodiments, the length L of the sacrificial oxide portions 232P, which determines the critical dimension of the metal gate stack (e.g., gate stack 270, as shown in FIG. 14) may range from 12 nm to 18 nm.

In some embodiments, the selective recess of the sacrificial oxide portions 232P may be implemented by an isotropic dry etching process using an etch gas composition including a halogen-containing compound, ammonia (NH₃), and an amine. In some embodiments, the halogen-containing compound is a hydrogen halide including hydrogen fluoride, hydrogen chloride, hydrogen bromide, hydrogen iodide, or combinations thereof. In some embodiments, the halogen-containing compound is a fluorine-containing compound. In some embodiments, the fluorine-containing compound may include, but not limited to, hydrogen fluoride (HF), carbon tetrafluoride (CF₄), trifluoromethane (CHF₃), sulfur hexafluoride difluoromethane (CH₂F₂) and hexafluoroethane (C₂F₆). In some embodiments, the amine may include, but not limited to, methylamine, dimethylamine, trimethylamine, ethylamine, diethylamine, triethylamine, methylethylamine, N, N-diethylmethylamine, N, N-dimethylethylamine, isopropylamine, N-ethyldiisopropylamine, and tert-butylamine. In some embodiments, the etch gas composition comprises hydrogen fluoride, ammonia, and trimethyl amine.

In some embodiments, the etch gas composition may further include a carrier gas, such as, for example, argon, nitrogen, helium, or combinations thereof.

The ammonia and amine gases act as catalysts in the halide oxide etching process. In some embodiments, a ratio of the flow rates of halogen-containing compound to the mixture of ammonia and amine may be from about 1:1 to about 1:2. The ratio of ammonia to amine flow rates is adjusted to control top-to-bottom etching rates for the stack of sacrificial oxide portions 232P, ensuring uniform lateral etch depth. Precise control of the oxide's critical dimension (CD) from top to bottom enables the formation of a metal gate with an improved CD after replacing the sacrificial oxide portions 232P in subsequent processes, resulting in enhanced device performance. In some embodiments, the ratio of ammonia to amine flow rates in the etchant composition is from 1:5 to 5:1. If the ratio of the ammonia to amine flow rate is too low, the etching rate may become too slow, causing the inner spacers 240 to become too thin to adequately protect the source/drain features 250, which leads to poor yield. Conversely, if the ratio of ammonia to amine flow rates is too high, the etching rate may become difficult to control, resulting in over-etching or substantially non-uniform etching of the sacrificial oxide portions 232P from top to bottom, which leads to poor device performance. In some embodiments, the ratio of ammonia to amine flow rates is from 1:3 to 3:1. In some embodiments, the ratio of ammonia to amine flow rates is 1:1.

The selective etching process is cyclic, consisting of two steps in each cycle: a reaction step followed by a by-product removal step. In the reaction step, gaseous reactants, including a halogen-containing compound, ammonia, and amine, are introduced into a processing chamber to effect the selective etching of the sacrificial oxide portions 232P. The reaction conditions may include a gas pressure within the processing chamber ranging from about 100 millitorrs (mTorr) to about 3,000 mTorr, a temperature ranging from about 20° C. to 70° C., and a duration ranging from about 50 seconds to about 5 minutes. In some embodiments, the etching reaction is carried out at a low process environment. The low pressure may be in the range from 100 mTorr to 600 mTorr, such as 400 mTorr. The flow rate for the halogen-containing compound may range from about 50 standard cubic centimeters per minute (sccm) to about 500 sccm, while the total flow rate for the ammonia and amine can vary from about 50 sccm to about 500 sccm. If a carrier gas is present, the flow rate of carrier gas may range from about 20 sccm to 100 sccm. Plasma may be generated during the reaction step; alternatively, the plasma may not be activated.

When the GAA device 200 of FIG. 7 is exposed to the etch gas composition under these conditions, the halogen-containing compound, ammonia, and amine etch gases are adsorbed onto the surfaces of the sacrificial oxide portions 232P, initiating surface etching. Amine gas tends to be more easily adsorbed on the top side of the sacrificial oxide stack, while ammonia gas is more easily adsorbed at the bottom. By controlling the flow rates of ammonia and amine within the specified range, uniform etching rates for the sacrificial oxide portions 232P can be achieved from top to bottom. In the reaction step, a solid by-product, comprising ammonium fluorosilicate ((NH₄)₂SiF₆) and an alkylated derivate of (NH₄)₂SiF₆, forms on the surfaces of the sacrificial oxide portions 232P.

The by-product removal step involves decomposing the solid by-product into volatile species, which are then evacuated or purged from the processing chamber. In some embodiments, the carrier gas may also function as a purging gas. In some embodiments, thermal treatment may be performed to thermally decompose the solid by-product. In some embodiments, the thermal treatment may be carried out at a temperature ranging from about 80° C. to about 200° C.

In some embodiments, the selective etching process may be a single cycle, involving only one reacting operation and one removal operation. In other embodiments, multiple cycles may be employed to achieve the desired etching effect.

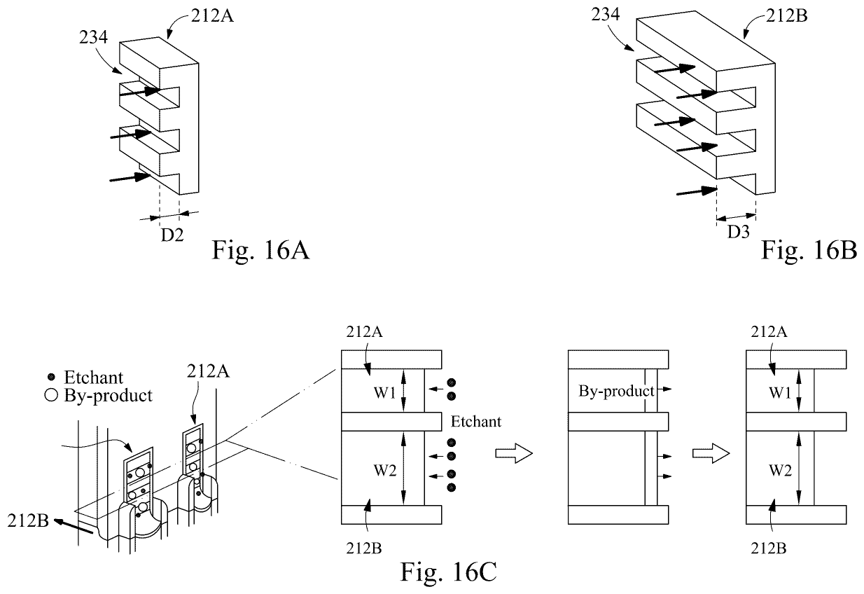

It is well known that when features of varying widths are etched simultaneously, the aspect ratio dependent etching (ARDE) effect causes wider features to etch at faster rates, resulting in a larger lateral etch distance. As illustrated in FIGS. 15A and 15B, under identical etching conditions, the sacrificial oxide portions 232P in the narrower fin structure 212A (FIG. 16A) etch more slowly than the wider sacrificial oxide portions 232P in the wider fin structure 212B (FIG. 16B). As a result, the lateral openings 234 in fin structure 212A have a lateral etching distance D2 less than the lateral etching distance D3 of the lateral openings 234 in fin structure 212B.

To achieve a uniform etching distance in the sacrificial oxide portions 232P of varying widths across the substrate 202, the etching cycle is repeated at least six (6) times to ensure that the etching distance, defined as the thickness of sacrificial oxide portions 232P removed after each cycle, does not exceed 1.5 nm/cycle. In some embodiments, the etching cycle may be repeated 7, 8, 10, 15, 20, 30, 40, 50, or even 100 times to remove the desired amount of oxide. By utilizing multiple etching cycles to maintain a low etching rate during each cycle, a uniform lateral etching distance can be achieved in sacrificial oxide portions 232P of different widths across the substrate 202 (FIG. 16C).

Referring to FIGS. 1 and 9, the method 100 proceeds to operation 116, where inner spacers 240 are formed in the lateral openings 234, in accordance with some embodiments. FIG. 9 a cross-sectional view of the GAA device 200 after forming the inner spacers 240.

An inner spacer material layer is deposited over the structure including in the lateral openings 234. The inner spacer material may include a dielectric nitride, for example, silicon nitride, silicon oxycarbonitride, silicon carbonitride, or any suitable dielectric materials having different etching selectivity from the dielectric oxide constituting the sacrificial oxide portions 232P. The inner spacer material layer may be formed by CVD, ALD or any other suitable conformal deposition processes. In some embodiments, the inner spacer material layer may be formed to have a thickness such that the lateral openings 234 are completely filled by the inner spacer material layer.

An etching process, such as an anisotropic etching process, is then performed to remove portions of the inner spacer material layer disposed outside the lateral openings 234. The remaining portions of the inner spacer material layer (i.e., portions disposed inside the inner spacer recesses) form the inner spacers 240. In some embodiments, the anisotropic etching process may be a wet etching process that includes use of an etchant such as, for example, buffered hydrofluoric acid (BHF), hydrofluoric acid (HF), hydrofluoric nitric acid (HNA), phosphoric acid, HF diluted by ethylene glycol (HFEG), hydrochloric acid (HCl), or any combination thereof. In some embodiments, the anisotropic etching process may be a dry etching process that includes use of an oxygen-containing gas, hydrogen, nitrogen, a fluorine-containing gas (e.g., CF₄, SF₆, CH₂F₂, CHF₃, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas (e.g., CF₃I), other suitable gases and/or plasmas, and/or combinations thereof.

Referring to FIGS. 1 and 10, the method 100 proceeds to operation 118, where source/drain features 250 are formed in the source/drain trenches 228, in accordance with some embodiments. FIG. 10 is a cross-sectional view of the GAA device 200 after forming the source/drain features 250. The source/drain features 250 are disposed on opposite sides of the dummy gate structure 220, the channel semiconductor portions 208P, and the sacrificial oxide portions 232P such that the source/drain features 250 are in contact with the channel semiconductor portions 208P but are separated from the sacrificial oxide portions 232P by the inner spacers 240.

The source/drain features 250 are epitaxially grown in the source/drain trenches 228. The epitaxy process may include CVD deposition (for example, vapor-phase epitaxy (VPE) ultra-high vacuum CVD (UHV-CVD), low pressure CVD (LPCVD), plasma-enhanced CVD (PECVD), molecular beam epitaxy (MBE), other suitable selective epitaxy growth (SEG) processes, or combinations thereof. Due to the fact that the substrate 202 in the source/drain trenches 228 is covered by the isolation feature 216, there is no nucleation site at the bottom during the source/drain epitaxy growth. As a result, the source/drain features 250 grow laterally from the exposed sidewalls of the channel semiconductor portions 208P and the base portion 210B if exposed by the isolation feature 216.

The source/drain features 250 may include any suitable material for n-type or p-type FET devices. For example, when n-type FET devices are formed, the source/drain features 250 may include materials exerting a tensile strain in the channel regions, such as Si, SiC, SiCP, SiP, or the like, and may be in-situ doped during the epitaxy process by introducing an n-type dopant, such as phosphorus (P), arsenic (As), or ex-situ doped using an implantation process (i.e., a junction implant process). Likewise, when p-type FET devices are formed, the source/drain features 250 may include materials exerting a compressive strain in the channel regions, such as Si, SiGe, SiGeB, Ge, GeSn, or the like and may be in-situ doped during the epitaxy process by introducing a p-type dopant, such as boron (B), aluminum (Al), gallium (Ga), and indium (In), or ex-situ doped using an implantation process (i.e., a junction implant process). The source/drain features 250 may have surfaces raised from respective surfaces of the channel semiconductor portions 208P and may have facets. In some embodiments, the source/drain features 250 are p-type source/drain features and include boron-doped SiGe. In some embodiments, the source/drain features 250 are n-type source/drain features and include phosphorus-doped Si.

In some embodiments, a thermal anneal process is performed following the epitaxial growth and doping of the source/drain features 250. This process causes dopants to be injected into portions of the channel semiconductor portions 208P that are in contact with the source/drain features 250. This anneal process effectively extends the source/drain features 250 into the end portions of the channel semiconductor portions 208P, reducing parasitic resistance of the nanosheet transistor. In other embodiments, the thermal anneal process is performed in a later process (such as after the formation of the high-k gate dielectric layers) so that the same anneal process can serve two purposes at the same time: driving dopants into the channel semiconductor portions 208P, and improving the reliability of the high-k gate dielectric. In some embodiments (not shown), after annealing, sidewalls of the source/drain features 250 are aligned with the inner sidewalls of the gate spacers 226. In some other embodiments, the thermal anneal process is omitted, and the sidewall of the source/drain features 250 are aligned with the outer sidewalls of the gate spacers 226 (FIG. 10).

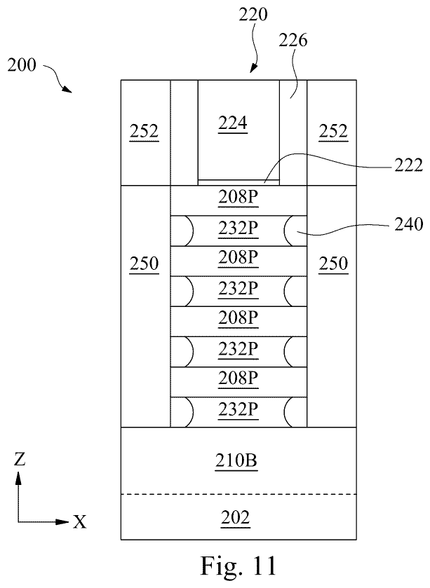

Referring to FIGS. 1 and 11, the method 100 proceeds to operation 120, where an interlayer dielectric (ILD) layer 252 is formed over the source/drain features 250 and the isolation features 216, in accordance with some embodiments. FIG. 11 is a cross-sectional view of the GAA device 200 after forming the ILD layer 252.

In some embodiments, the ILD layer 252 may include a low-k dielectric material having a dielectric constant lower than the dielectric constant (about 3.9) of silicon dioxide. The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOₓC_{y}), spin-on-glass (SOG), or combinations thereof. The ILD layer 252 may include a multi-layer structure having multiple dielectric materials and may be formed by CVD, flowable CVD (FCVD), spin coating, or other suitable deposition processes. In some embodiments, forming the ILD layer 252 further includes performing a CMP process to planarize a top surface of the ILD layer 252, such that the dummy gate electrode 224 is exposed. The top surface of the ILD layer 252 may be coplanar with the top surfaces of the dummy gate electrode 224 and the gate spacers 226.

Referring to FIGS. 1 and 12, the method 100 proceed to operation 122, where the dummy gate stack including the dummy gate dielectric 222 and the dummy gate electrode 224 are removed, in accordance with some embodiments. FIG. 12 is a cross-sectional view of the GAA device 200 after removing the dummy gate stack (222, 224).

An etching process selectively removes the dummy gate dielectric 222 and the dummy gate electrode 224, thereby forming a gate trench 254 that exposes the channel semiconductor portions 208P and the sacrificial oxide portions 232P in the channel regions of the GAA device 200. The ILD layer 252 protects the source/drain features 250 during the etching process. The etching process may be a dry etching process, a wet etching process, or a combination thereof. The etching process can be tuned such that the dummy gate dielectric 222 and the dummy gate electrode 224 are removed without (or minimally) etching other elements in the GAA device 200, including the ILD layer 252, the source/drain features 250, and the gate spacers 226. For example, in instances where the dummy gate electrode 224 is composed of polysilicon and the ILD layer 252 is composed of silicon oxide, a wet etchant such as a TMAH solution may be used to selectively remove the dummy gate electrode 224. The dummy gate dielectric 222 is thereafter removed using plasma dry etching and/or wet etching.

Referring to FIGS. 1 and 13, the method 100 proceeds to operation 124, where the sacrificial oxide portions 232P are removed, in accordance with some embodiments. FIG. 13 is a cross-sectional view of the GAA device 200 after removing the sacrificial oxide portions 232P.

The selective removal of the sacrificial oxide portions 232P releases the channel semiconductor portions 208P to form channel nanostructures 262. In some embodiments, the channel nanostructures 262 are nanosheets. In some embodiments, the sacrificial oxide portions 232P may be removed by a selective etching process using an etchant that is selective to the material of sacrificial oxide portions 232P, such that the sacrificial oxide portions 232P are removed without substantially attacking the channel semiconductor portions 208P, the gate spacers 226, the inner spacers 240, and the ILD layer 252. In some embodiments, the etching process is an isotropic etching process which can be a dry etching process or a wet etching process. The inner spacers 240 serve as etch stop layers to protect the source/drain features 250 during removal of the sacrificial oxide portions 232P.

In some embodiments, after exposing the channel nanostructures 262 by removing the sacrificial oxide portions 232P, a trimming operation may be performed to reduce the thickness of the channel nanostructures 262, thereby improving the gate fill window. The trimming operation can utilize any suitable etching process, such as dry etching, wet etching, or a combination of both. The resulting channel nanostructures 262 may have a thickness T1 ranging from 3 nm to 6 nm.

As shown in FIG. 13, gaps 256 (e.g., empty spaces) are formed between adjacent channel nanostructures 262 and between the bottommost channel nanostructure 262 and the base portion 210B, as a result of the removal of the sacrificial oxide portions 232P and nanosheet trimming. The gaps 256 define the spacing S2 between adjacent channel nanostructures 262. In some embodiments, the spacing S2 between the adjacent channel nanostructures 262 (also referred to as sheet-to-sheet spacing) may range from about 8 nm to about 15 nm.

Referring to FIGS. 1 and 14, the method 100 proceeds to operation 124, where a gate stack 270 is formed in the gate trench 254 and the gaps 256, in accordance with some embodiments. FIG. 14 is a cross-sectional view of the GAA device 200 after forming the gate stack 270. The gate stack 270 is deposited over and between the channel nanostructures 262. In some embodiments, the gate stack 270 includes an interfacial layer 272, a gate dielectric layer 274, a work function layer 276, and a gate electrode layer 278.

The interfacial layer 272 is formed on the exposed surfaces of the channel nanostructures 262 and the base portion 210B. The interfacial layer 272 promotes adhesion of the gate dielectric layer 274 to the channel nanostructures 262. In some embodiments, the interfacial layer 272 may include a dielectric material such as silicon oxide. In some embodiments, the interfacial layer 272 may be formed by chemical oxidation or thermal oxidation of surface portions of the channel nanostructures 262 and the base portion 210B. For example, in some embodiments, the interfacial layer 272 is formed using an ozonated deionized water comprising ozone. The thickness of the interfacial layer 272 ranges from about 0.5 nm to about 1.5 nm. In some embodiments, the interfacial layer 272 is about 1 nm thick, achieved by oxidizing around 1 nm of the channel nanostructures 262.

Afterwards, the gate dielectric layer 274 is conformally deposited over the interfacial layer 272. The gate dielectric layer 274 wraps around the channel nanostructures 262, and is on the sidewalls of the gate trench 254. In some embodiments, the gate dielectric layer 274 may include a high-k dielectric material having a dielectric constant greater than silicon dioxide. Examples of high-k dielectric materials include, but are not limited to, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), zirconium oxide (ZrO₂), aluminum oxide (Al₂O₃), titanium oxide (TiO₂), and hafnium oxide-alumina (HfO₂—Al₂O₃) alloy. The gate dielectric layer 274 may be formed by CVD, ALD or other suitable conformal deposition methods. In some embodiments, the gate dielectric layer 274 is formed using a conformal deposition process such as ALD in order to ensure that the high-k gate dielectric layer 274 has a uniform thickness around each of channel nanostructures 262. The gate dielectric layer 274 may be formed to have a thickness ranging from about 1 nm to about 2.5 nm. In some embodiments, the gate dielectric layer 274 may be formed to have a thickness of about 1.5 nm.

Subsequently, a work function layer 276 is deposited over the gate dielectric layer 274. For an n-type FET, the work function layer 276 may include an n-type work function layer adapted to tune the threshold voltage for n-type FET. Suitable n-type work function materials include, but are not limited to, aluminum (Al), titanium aluminum (TiAl), titanium aluminum carbide (TiAlC), tantalum aluminum carbide (TaAlC), tantalum aluminum silicide (TaSiAl), tantalum silicon carbide (TaSiC), tantalum silicide (TaSi), hafnium carbide (HfC), and combinations thereof. For a p-type FET, the work function layer 276 may include a p-type work function layer adapted to tune the threshold voltage for p-type FET. In some embodiments, the p-type work function layer includes tungsten (W), molybdenum (Mo), tungsten nitride (WN), tungsten carbon nitride (WCN), tantalum silicon nitride (TaSiN), or tantalum nitride (TaN). The work function layer may be formed by a conformal deposition process such as, for example, ALD or CVD. In some embodiments, the work function layer 276 may be formed to have a thickness ranging from about 1.5 nm to about 2.5 nm.

Subsequently, the gate electrode layer 278 is formed on the work function layer 276 to fill any remaining volumes in the gate trench 254 and the gaps 256. The gate electrode layer 278 may include a conductive material such as tungsten, cobalt, ruthenium, iridium, molybdenum, copper, aluminum, or combinations thereof. The gate electrode layer 278 may be formed by any suitable deposition process such as CVD, PECVD, PVD, or electrochemical plating.

Next, excess portions of the gate dielectric layer 274, the work function layer 276, and the gate electrode layer 278 that are deposited on the top surface of the ILD layer 252 and the gate spacers 226 are removed in a planarization process such as a CMP process to form the gate stack 270. The top surface of the gate stack 270 may be coplanar with the top surfaces of the ILD layer 252 and the gate spacers 226.

The gate stack 270 thus formed surrounds the channel nanostructures 262 and fills the gaps 256 between the channel nanostructures 262 and between the bottommost channel nanostructure 262 and the base portion 210B. Between the channel nanostructures 262, the gate electrode layer 278 is circumferentially surrounded (in the cross-sectional view) by the work function layer 276, which is then circumferentially surrounded by the gate dielectric layer 274.

In the portion of the gate stack 270 formed over the topmost channel nanostructure 262, the gate electrode layer 278 is formed over the work function layer 276 with the work function layer 276 wrapping around the gate electrode layer 278 and the gate dielectric layer 274 wrapping around the work function layer 276.

Additional processing may be performed to finish the fabrication of the GAA device 200. For example, gate contact (not illustrated for simplicity) and the source/drain contacts may be formed to electrically couple to the gate stack 270 and the source/drain features 250, respectively. An interconnect structure may then be formed over the source/drain contacts and the gate contact. The interconnect structure may include a plurality of dielectric layers surrounding metallic features, including conductive traces and conductive vias, which form electrical connection between devices on the substrate 202, such as the GAA device 200.

In embodiments of the present, by adjusting the ratio of the flow rates of ammonia to amine gases and the number of etching cycles, a uniform lateral etching rate from top to bottom in GAA devices, ensuring the formation of inner spacers with a uniform width. This control over metal gate critical dimensions (CD) can be effectively applied to GAA devices with both same and different channel widths, leading to enhanced device performance.

One aspect of this description relates to a method for forming a semiconductor device. The method includes forming a stack over a substrate. The stack includes multiple semiconductor portions spaced apart from one another by gaps. The gaps are then filled with a dielectric oxide material. Next, end portions of the deposited dielectric oxide material are laterally etched by an etch gas composition to form lateral openings. The etch gas composition includes a halogen-containing compound, ammonia and an amine. Next, inner spacers are formed in the lateral openings between the adjacent semiconductor portions of the multiple semiconductor portions. Next, the remaining portions of the deposited dielectric oxide material in the gaps are removed. Next, a gate stack is formed in the gaps to surround a channel region of the stack.

Another aspect of this description relates to a method for forming a semiconductor device. The method includes forming a fin structure over a substrate, the fin structure comprising alternatively stacked first semiconductor portions and second semiconductor portions. A dummy gate structure comprising a dummy gate stack and gate spacers on sidewalls of the dummy gate stack is formed. The dummy gate stack across a channel region of the fin structure. Next, portions of the fin structure not covered by the dummy gate structure are removed to form source/drain trenches. Next, the first semiconductive portions are selectively removed to release the second semiconductor portions in the channel region. Next, sacrificial oxide portions are formed to fill gaps between the second semiconductor portions. Next, end portions of the sacrificial oxide portions are laterally recessed to form lateral openings. The laterally recessing is implemented using an etch gas composition comprising a halogen-containing compound, ammonia and an amine. Next, inner spacers are formed in the lateral openings and source/drain features are formed in the source/drain trenches. Next, the dummy gate stack are removed to form a gate trench exposing sidewalls of the second semiconductor portions and the sacrificial oxide portions. After removing the sacrificial oxide portions in the gaps, a gate stack is formed to surround the second semiconductor portions, wherein the gate stack fills the gaps.

Still another aspect of this description relates to a method for forming a semiconductor device. The method includes forming a first stack and a second stack over a substrate. The first stack includes multiple first semiconductor portions of a first width spaced apart from one another by first gaps, and the second stack includes multiple second semiconductor portions of a second width spaced apart from one another by second gaps. The first width is less than the second width. After filing the first and second gaps with a dielectric oxide material, end portions of the deposited dielectric oxide material are laterally etched to form lateral openings by performing a plurality of cycles that includes exposing the deposited dielectric oxide material to an etch gas composition to modify surfaces of the end portions of the deposited dielectric oxide material and removing the modified surface portion of the deposited dielectric oxide material by thermal treatment. Next, a dielectric material is deposited in the lateral openings to form inner spacers positioned between the adjacent first semiconductor portions of the multiple first semiconductor portions and the adjacent second semiconductor portions of the multiple second semiconductor portions. After removing the remaining portions of the deposited dielectric oxide material in the first and second gaps, a gate stack is formed in the gaps to surround a channel region of each of the first and second stacks.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for forming a semiconductor device, comprising:
forming a stack over a substrate, the stack comprising multiple semiconductor portions spaced apart from one another by gaps;
filing the gaps with a dielectric oxide material;
laterally etching end portions of the deposited dielectric oxide material by an etch gas composition to form lateral openings, the etch gas composition comprising a halogen-containing compound, ammonia and an amine;
forming inner spacers in the lateral openings between the adjacent semiconductor portions of the multiple semiconductor portions;
removing remaining portions of the deposited dielectric oxide material in the gaps; and
forming a gate stack in the gaps to surround a channel region of the stack.

2. The method of claim 1, wherein the halogen-containing compound comprises hydrogen fluoride (HF), carbon tetrafluoride (CF₄), trifluoromethane (CHF₃), sulfur hexafluoride difluoromethane (CH₂F₂) or hexafluoroethane (C₂F₆).

3. The method of claim 2, wherein the amine comprises methylamine, dimethylamine, trimethylamine, ethylamine, diethylamine, triethylamine, methylethylamine, N, N-diethylmethylamine, N, N-dimethylethylamine, isopropylamine, N-ethyldiisopropylamine or tert-butylamine.

4. The method of claim 3, wherein the etch gas composition comprises hydrogen fluoride, ammonia, and trimethyl amine.

5. The method of claim 1, wherein a ratio of ammonia to amine flow rates is from 1:3 to 3:1.

6. The method of claim 1, wherein the etch gas composition further comprises a carrier gas.

7. The method of claim 1, wherein a ratio of flow rates of the halogen-containing compound to a mixture of ammonia and amine is from 1:1 to 1:2.

8. The method of claim 1, filling the gaps with the dielectric oxide material comprises:
conformally depositing an oxide layer comprising silicon oxide to pinch off the gaps; and
removing portions of the oxide layer outside the gaps.

9. The method of claim 1, wherein a critical dimension of the gate stack within each gap is from 12 nm to 18 nm.

10. The method of claim 1, wherein forming inner spacers in the lateral openings comprises depositing a dielectric nitride material in the lateral openings.

11. A method for forming a semiconductor device, comprising:
forming a fin structure over a substrate, the fin structure comprising alternatively stacked first semiconductor portions and second semiconductor portions;
forming a dummy gate structure comprising a dummy gate stack and gate spacers on sidewalls of the dummy gate stack, the dummy gate stack across a channel region of the fin structure;
removing portions of the fin structure not covered by the dummy gate structure to form source/drain trenches;
selectively removing the first semiconductive portions to release the second semiconductor portions in the channel region;
forming sacrificial oxide portions to fill gaps between the second semiconductor portions;
laterally recessing end portions of the sacrificial oxide portions to form lateral openings, wherein the laterally recessing is implemented using an etch gas composition comprising a halogen-containing compound, ammonia and an amine;
forming inner spacers in the lateral openings;
forming source/drain features in the source/drain trenches;
removing the dummy gate stack to form a gate trench exposing sidewalls of the second semiconductor portions and the sacrificial oxide portions;
removing the sacrificial oxide portions in the gaps; and
forming a gate stack to surround the second semiconductor portions, wherein the gate stack fills the gaps.

12. The method of claim 11, wherein the halogen-containing compound comprises hydrogen fluoride (HF), carbon tetrafluoride (CF₄), trifluoromethane (CHF₃), sulfur hexafluoride difluoromethane (CH₂F₂) or hexafluoroethane (C₂F₆).

13. The method of claim 12, wherein the amine comprises methylamine, dimethylamine, trimethylamine, ethylamine, diethylamine, triethylamine, methylethylamine, N, N-diethylmethylamine, N, N-dimethylethylamine, isopropylamine, N-ethyldiisopropylamine or tert-butylamine.

14. The method of claim 13, wherein the etch gas composition comprises hydrogen fluoride, ammonia, and trimethyl amine.

15. The method of claim 14, wherein a ratio of ammonia to amine flow rates is from 1:3 to 3:1.

16. The method of claim 11, wherein a ratio of flow rates of the halogen-containing compound to a mixture of ammonia and amine is from 1:1 to 1:2.

17. A method for forming a semiconductor device, comprising:
forming a first stack and a second stack over a substrate, the first stack comprising multiple first semiconductor portions of a first width spaced apart from one another by first gaps, and the second stack comprising multiple second semiconductor portions of a second width spaced apart from one another by second gaps, wherein the first width is less than the second width;
filing the first and second gaps with a dielectric oxide material;
laterally etching end portions of the deposited dielectric oxide material to form lateral openings by performing a plurality of cycles comprising:
exposing the deposited dielectric oxide material to an etch gas composition to modify surfaces of the end portions of the deposited dielectric oxide material, the etch gas composition comprising a halogen-containing compound, ammonia and an amine; and
removing the modified surface portions of the deposited dielectric oxide material by thermal treatment;
depositing a dielectric material in the lateral openings to form inner spacers positioned between the adjacent first semiconductor portions of the multiple first semiconductor portions and the adjacent second semiconductor portions of the multiple second semiconductor portions;
removing remaining portions of the deposited dielectric oxide material in the first and second gaps; and
forming a gate stack in the first and second gaps to surround a channel region of each of the first and second stacks.

18. The method of claim 17, wherein the halogen-containing compound comprises hydrogen fluoride (HF), carbon tetrafluoride (CF₄), trifluoromethane (CHF₃), sulfur hexafluoride difluoromethane (CH₂F₂) or hexafluoroethane (C₂F₆).

19. The method of claim 17, wherein the amine comprises methylamine, dimethylamine, trimethylamine, ethylamine, diethylamine, triethylamine, methylethylamine, N, N-diethylmethylamine, N, N-dimethylethylamine, isopropylamine, N-ethyldiisopropylamine or tert-butylamine.

20. The method of claim 17, wherein an etching distance in each cycle of the plurality of cycles is less than 1.5 nm/cycle.
